(19) United States
(12) Patent Application Publication
(10) Pub. No.: US 2020/0156930 A1
(43) Pub. Date: May 21, 2020

(54) MICROMECHANICAL COMPONENT

(71) Applicant: Robert Bosch GmbH, Stuttgart (DE)

(72) Inventors: Johannes Classen, Reutlingen (DE); Laszlo Gogh, Diosd (HU)

(21) Appl. No.: 16/681,124

(22) Filed: Nov. 12, 2019

(30) Foreign Application Priority Data
Nov. 15, 2018 (DE) 102018219546.3

(51) Int. Cl. B81B 5/00; G01P 15/08; G01P 15/125; B81B 3/00; G01C 19/5747

(52) U.S. Cl. CPC B81B 5/00; G01P 15/0802; G01P 15/125; B81B 3/007; B81B 2201/0242; G01P 2015/0805; B81B 2201/0235; B81B 2203/01; G01C 19/5747

(57) ABSTRACT

A micromechanical component having a movable seismic mass developed in a second and third silicon functional layer, a hollow body being developed in the second and third silicon functional layers, which has a cover element developed in a fourth silicon functional layer.

### CROSS REFERENCE

The present application claims the benefit under 35 U.S.C. § 119 of German Patent Application No. 102018219546.3 filed on Nov. 15, 2018, which is expressly incorporated herein by reference in its entirety.

### FIELD

The present invention relates to a micromechanical component. The present invention further relates to a method for producing a micromechanical component.

### BACKGROUND INFORMATION

Micromechanical components, e.g., inertial sensors for measuring acceleration and rate of rotation, are manufactured in mass production for various applications in the automotive and consumer sectors. Rocker structures are preferably used for capacitive acceleration sensors having a detection direction perpendicular to the wafer plane (i.e., in the z-direction). The sensor principle of these rockers is based on a spring-mass system in which in the simplest case a movable seismic mass having two counter electrodes fixed on a substrate forms two plate capacitors. The seismic mass is connected to the base via at least one, for reasons of symmetry usually two torsion springs. If the mass structures on the two sides of the torsion spring are of different size, then a z-acceleration action will induce the mass structure to rotate relative to the torsion spring as axis of rotation. The distance of the electrodes on the side having the greater mass therefore becomes smaller and greater on the other side. The change in the capacitance is a measure for the acting acceleration. Such acceleration sensors are described, for example, in European Patent Application Nos. from EP 0 244 581 A1 and EP 0 773 443 A1.

Various methods have been proposed for compensating for the influence of surface potentials on acceleration sensors, e.g., in German Patent No. DE 103 50536 B3, German Patent Application No. DE 10 2006 057 929 A1, and German Patent Application No. DE 10 2008 040 567 A1. All of the proposals described therein have in common that the problem of the offset drifts is to be solved via special measures and provisions on the circuit side and/or by special test methods. Such measures are very laborious, however, and thus result in significant additional costs of the components.

Some years ago, novel z-sensor designs and technologies were proposed, in German Patent Application No. DE 10 2009 000167 A1 for example, in order, among other things, to improve the parasitic effects due to electrical surface potentials without intervention on the circuit side. German Patent Application No. DE 10 2009 000167 A1 describes a substantially improved robustness vis-a-vis surface potentials and their drifts, since the lower side of the movable structure, which is formed by the second functional layer, was electrically symmetrized vis-a-vis the conductor track plane. The mass asymmetry required for the mechanical sensitivity is here achieved via a third functional layer.

Even these greatly improved structures, however, are in turn sensitive to surface potentials if the upper side of the movable seismic mass in the third functional layer 30 is faced by another electrically conductive plane having parasitic capacitances and resulting parasitic forces, as shown in FIG. 5. The additional conductive plane may be e.g. the uppermost metallization plane of a CMOS wafer, which was bonded on the MEMS wafer as a cap, as is described in, e.g., German Patent Application No. DE 10 2012 208 032 A1. Instead of the CMOS wafer, this may also be a simple Si sensor cap having a small spacing with respect to the movable sensor structure or a cap having one or multiple wiring planes.

While in the design of FIG. 5, it is possible to implement the interaction of the movable structure with the conductor track areas on the lower side (between first functional layer 10 and second functional layer 20) to be torque-free, the interaction on the upper side, that is, between third functional layer 30 and the uppermost metallization plane of the ASIC is not torque-free, since the interacting surfaces on the two sides of the torsion axis 33 are not identical. From the basic topology of the design, one is therefore thrown back to the situation of the designs of FIGS. 1 and 2, as far as the influence of surface potentials is concerned. Formulated differently, even the more advanced MEMS design of FIGS. 3 and 4 is subject to problems with respect to the sensitivity to surface potentials, as soon as a conductive cap is situated at a small distance from the upper side of the MEMS structure.

German Patent Application No. DE 10 2016 207 650 A1 describes a defined electrical partitioning of electrode surfaces on the cap wafer or in the first functional layer in the area of the additional mass in order to minimize the effects of charge drifts.

A further problem with respect to the boundary surfaces of an asymmetrical rocker design are possible radiometric effects, which may occur at in the event of rapid temperature changes. In such temperature changes, the temperatures of the rocker and the substrate are not in thermal equilibrium, but rather there are temperature gradients perpendicular to the substrate layer, it being possible that e.g. the substrate with the bottom electrodes in the first functional layer is somewhat warmer than the rocker structure in the third functional layer. The thermal gradients induce movements of the gas particles in the sensor cavity, the impacts of which with the movable sensor structure may result in measurable parasitic deflections of the rocker and thus result in offset signals. This effect is described in C. Nagel et al., “Radiometric effects in MEMS accelerometers”, IEEE Sensors 2017, Glasgow, Scotland.

The designs of the sensors of FIGS. 3, 4 symmetrized with respect to the first functional layer 10 also help with respect to the mentioned radiometric effects in comparison to the situation of the sensors of FIGS. 1, 2. In the event of a temperature gradient, similarly strong torques act on the trough-shaped mass on the light rocker side in FIG. 4 due to the molecule impacts as on the heavy side of the rocker so that the net angular momentum (i.e., the sum of the torques left and right of the torsion spring) is markedly reduced. However, in this case as well, an asymmetrical force or torque situation sets in if, as in the design of the sensor from FIG. 5, another surface is situated near the upper side of the movable structure. In this case, there may be temperature differences also between the cap wafer and the third functional layer 30, and again a significant influence of thermal gradients on the offset of the sensor may result, since the boundary surfaces between the cap wafer and the movable structure are developed asymmetrically relative to the torsion axis.

German Patent Application Nos. DE 10 2009 000 345 A1 and DE 10 2010 038 461 A1 describe rotation-rate sensors having trough-shaped or partially concave sensor masses in order on the one hand to produce top electrodes in the third functional layer and on the other hand to allow for masses that have a light construction, which may offer advantages with respect to their mechanical and electromechanical properties.

One disadvantage of such trough-shaped bodies, however, is the fact that in a drive movement excited parallel to the substrate plane (in-plane), no pure in-plane movement results due to the center of mass having shifted somewhat downward and therefore being below the center of the spring, but rather a small parasitic out-of-plane movement component occurs, which, as sketched in FIG. 6, may be represented as a superposition of a rotation around the center of mass of the trough mass (curved arrow) and a z-translation (straight arrow) (the movement amplitudes in FIG. 6 are drawn in exaggerated fashion for better clarity). Bottom electrodes C₁, C₂ are developed in first functional layer 10 for detecting masses m₁, m₂. Although the z-parasitic movement is greatly suppressed in the first order by the antiphase movement of two drive masses m₁ and m₂ generally used in rotation-rate sensors and the differential electrical evaluation, nevertheless slight asymmetries may form between the two oscillating masses or in the electrode configuration due to local process inhomogeneities/tolerances so that still certain interference signals, in particular quadrature signal, remain, which may deteriorate the signal-to-noise ratio or the offset stability of the sensor.

Micromechanically produced hollow structures are fundamentally known from applications of microfluidics, although these hollow structures are not movable MEMS structures. Hollow structures of a CMOS back end formed by metal oxide stacks are described, for example, in U.S. Pat. Nos. 8,183,650 B2 and 8,338,896 B2, and United States Patent Application No. US 2011 049 653 A1. The structures formed from metal oxide stacks have the disadvantage that the typical thicknesses of the individual functional layers are merely in the range of 1 μm or below.

The metal layers furthermore have thermal expansion coefficients and stress values that markedly differ from those of the surrounding oxide layers. Following the exposure of the structures, both the small thicknesses as well as the great differences in the material parameters of metals and oxides can result in great strain and warping and additionally in changes of the mechanical or geometrical properties across temperature or service life. This yields markedly inferior sensing properties in comparison to micromechanical components formed from silicon layers.

### SUMMARY

It is therefore an object of the present invention to provide an improved micromechanical component, in particular an improved micromechanical inertial sensor.

In accordance with the present invention, the objective may be achieved in accordance with a first aspect by an example micromechanical component having a movable seismic mass developed in a second and third silicon functional layer, a hollow body being developed in the second and third silicon functional layers, which has a cover element developed in a fourth silicon functional layer.

In this manner, a hollow body made of silicon layers is provided in the movable seismic mass, as a result of which the seismic mass exhibits minimized parasitic effects because surfaces of the rocker device are upwardly and downwardly symmetrized, dimensions of the surfaces upward and downward being largely identical. Since in addition the movable mass is developed from silicon functional layers, the micromechanical components according to the present invention have very favorable properties.

According to a second aspect of the present invention, the objective is achieved by a method for manufacturing a micromechanical component, having the steps:
providing a movable seismic mass developed in a second and third silicon functional layer,
a hollow body being developed in the second and third functional layers, which has a cover element developed in a fourth silicon functional layer.

Preferred developments of the example micromechanical component are the described herein.

One advantageous development of the micromechanical component in accordance with the present invention is characterized by the fact that additionally first electrodes are developed in a first silicon functional layer, the seismic mass being capable of functionally interacting with the first electrodes. This advantageously makes it possible capacitively to detect movements of the seismic mass perpendicular to the substrate plane.

Another advantageous development of the micromechanical component in accordance with the present invention is characterized by the fact that additionally second electrodes are developed in the second, third or fourth functional layers. In this manner, additional stationary electrodes are provided, which further improves the sensing behavior of the micromechanical component.

Another advantageous development of the micromechanical component according to the present invention is characterized by the fact that the layer thicknesses of the second, third and fourth silicon functional layers are greater than approx. 1 μm, which advantageously makes it possible to achieve high stiffness, low warping and large capacitance areas.

Another advantageous development of the micromechanical component according to the present invention is characterized by the fact that the layer thicknesses of the third silicon functional layer is greater than 8 μm, which advantageously makes it possible to achieve high stiffness, low warping and large capacitance areas.

Another advantageous development of the micromechanical component according to the present invention is characterized by the fact that layer thicknesses of the second and fourth silicon functional layers are similar in a defined manner. This ensures that a center of mass of the movable mass is well adjusted in relation to the center point of the spring axis, which largely prevents undesired parasitic movements of the movable mass in the z-direction.

Another advantageous development of the micromechanical component according to the present invention is characterized by the fact that layer thicknesses of the second and fourth silicon functional layers differ by maximally 50%, preferably by maximally 25%. This also makes it possible largely to avoid parasitic deflections of the movable mass in the z-direction.

Another advantageous development of the micromechanical component according to the present invention is characterized by the fact that, at least in sections, a ratio of an area coverage between the second and fourth silicon functional layers and the third silicon functional layer is between three and ten, preferably five. This supports an efficient production of the hollow space in the additional hollow mass using conventional surface micromechanical processes.

The present invention is described below in detail with additional features and advantages with reference to several figures. Identical or functionally identical elements bear the same reference symbols. The figures are intended in particular to elucidate the main principles of the present invention and are not necessarily executed true to scale. For the sake of clarity, it may be provided that not all reference symbols are drawn in all figures.

Disclosed method features result analogously from corresponding disclosed device features and vice versa. This means in particular that features, technical advantages and embodiments relating to the micromechanical component analogously result from corresponding embodiments, features and advantages of the method for operating a micromechanical component and vice versa.

### BRIEF DESCRIPTION OF THE DRAWINGS

FIG. 1 shows a perspective view of a conventional micromechanical z-acceleration sensor.

FIG. 2 shows the conventional z-acceleration sensor from FIG. 1 in a cross-sectional view.

FIG. 3 shows a perspective view of another conventional micromechanical z-acceleration sensor.

FIG. 4 shows the conventional z-acceleration sensor from FIG. 3 in a cross-sectional view.

FIG. 5 shows a cross-sectional view of another conventional micromechanical z-acceleration sensor.

FIG. 6 shows an illustration of a problem of a conventional rotation-rate sensor.

FIG. 7 shows a cross-sectional view of a specific embodiment of a micromechanical z-acceleration sensor provided by the present invention.

FIG. 8 shows a cross-sectional view of another specific embodiment of a micromechanical z-acceleration sensor provided by the present invention.

FIG. 9 shows an illustration of a solved problem of a rotation-rate sensor of the invention.

FIGS. 10A and 10B show a basic sequence of a method for manufacturing a micromechanical component provided by the present invention in multiple partial illustrations.

FIG. 11 shows a basic sequence of a method for manufacturing a micromechanical component provided by the present invention.

### DETAILED DESCRIPTION OF EXAMPLE EMBODIMENTS

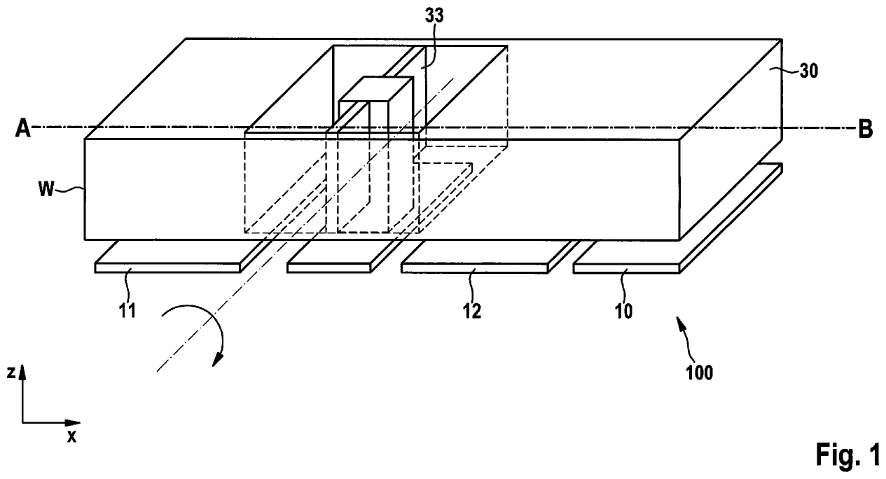

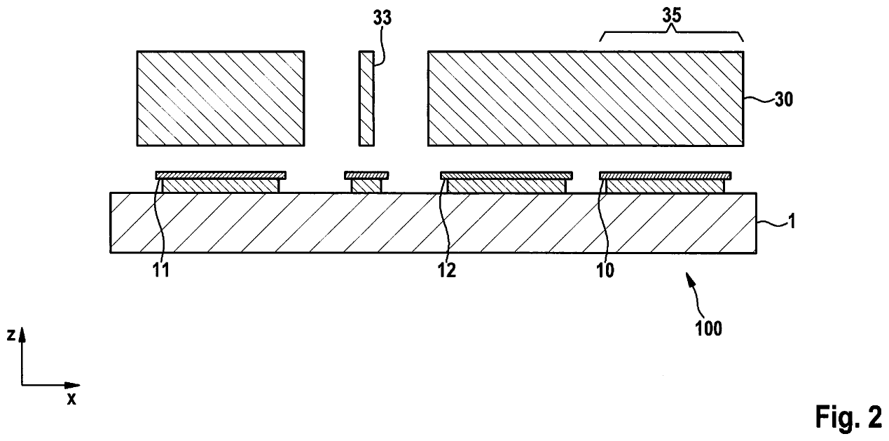

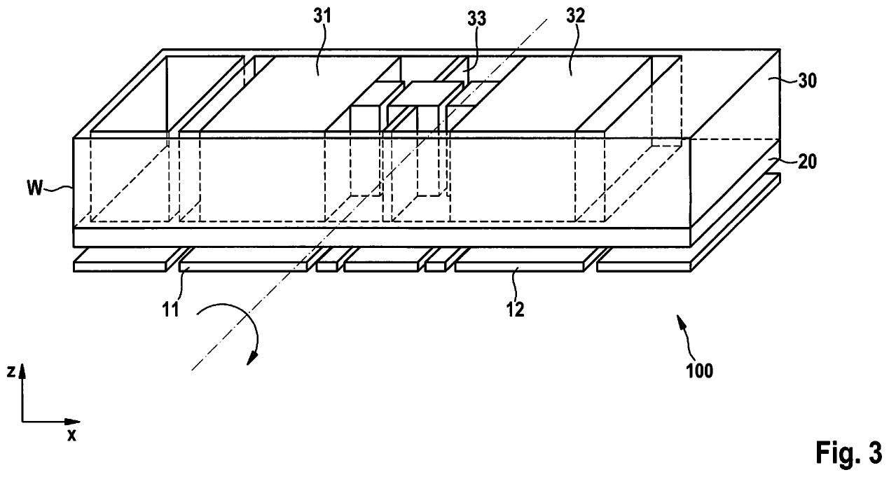

FIGS. 1, 2 show a conventional micromechanical z-acceleration sensor 100, FIG. 2 representing a simplified sectional view through a plane running perpendicularly to the substrate along the connecting line A-B in FIG. 1. It may be seen that the bottom electrodes 11, 12 developed in first micromechanical functional layer 10 are situated on a first oxide layer, which is situated on a substrate. Furthermore, an asymmetrically developed seismic mass in the shape of a rocker may be seen, which is developed to be rotatable about a torsion axis 33. An additional mass 35 effects an asymmetrical development of the seismic mass.

Such standard rockers are simply constructed and widely used, but have some technical problems, which hamper applications with very high requirements regarding offset stability. A significant limitation of the offset stability may be brought about by parasitic electrostatic effects, which are explained below.

For the capacitive evaluation, an electrical effective voltage, for example a pulsed electrical square-wave voltage is applied to the movable structure. In the area of the additional mass, electrostatic forces therefore act between the movable structure and the substrate as soon as an electrical potential difference occurs between the movable structure and the substrate. The forces or the resulting torques result in a parasitic deflection of the rocker. To minimize the electrostatic interaction, an additional conductor track surface is therefore usually situated on the substrate in the area of the additional mass, which has the same potential applied to it as the movable structure.

Theoretically, a freedom from forces may be achieved thereby between the additional mass and the substrate. In practice, however, significant surface charges or effective surface potentials may be present on the conductor track surface connected to the substrate and/or on the lower side of the movable structure, which can still result in parasitic forces and thus in electrical offset signals. These effects are particularly critical if they change across temperature or service life of the product since this results in offset drifts that cannot be corrected by the final calibration of the component.

A core idea of the present invention is in particular to create a micromechanical component, in particular an inertial sensor, having an improved offset stability and sensing characteristic.

In the micromechanical component of the present invention, a symmetrization of sensor masses with respect to parasitic forces (e.g., electrostatic and radiometric forces) is provided when two boundary surfaces exist, both below as well as above movable masses. This is achieved while simultaneously maintaining the mass asymmetries.

Furthermore, it is possible to exploit the advantages of light construction masses for rotation-rate sensors without having to accept parasitic movements of trough-shaped oscillating masses.

Furthermore, a surface micromechanical production method is provided for manufacturing hollow masses for movable MEMS structures.

The mentioned advantages are achieved in accordance with the present invention by a formation of hollow masses for movable MEMS structures, which are formed from three silicon functional layers as well as by a corresponding surface micromechanical production method for manufacturing such hollow masses.

For micromechanical z-acceleration sensors, it is thus possible to achieve a symmetrization with respect to parasitic forces or torques (e.g., electrostatic or radiometric forces/torque) on the upper and lower sides of the movable structure.

For rotation-rate sensors, it is possible in this manner to build very light, but at the same time stiff sensor masses, whose z-coordinate of the mass center of the mass is, in contrast to trough-shaped bodies, at the same elevation as the z-coordinate of the mass center of the spring so that in an in-plane-movement no or only extremely weak parasitic z-movements occur.

By using silicon as functional layer material, it is possible to achieve very favorable mechanical properties having a high temperature stability and service life stability.

The thicknesses of the silicon functional layers may preferably be selected to be relatively great, in particular greater than 1 μm. It is thus possible to build hollow masses that are very stiff and that barely tend to twist or warp.

It is furthermore advantageous to design at least one of the silicon functional layers, preferably the third silicon functional layer, to be particularly thick in order to achieve great masses, high stiffness values and large capacitance areas. Particularly advantageous are layer thicknesses for the third silicon functional layer greater than 8 μm, e.g. 10-50 μm.

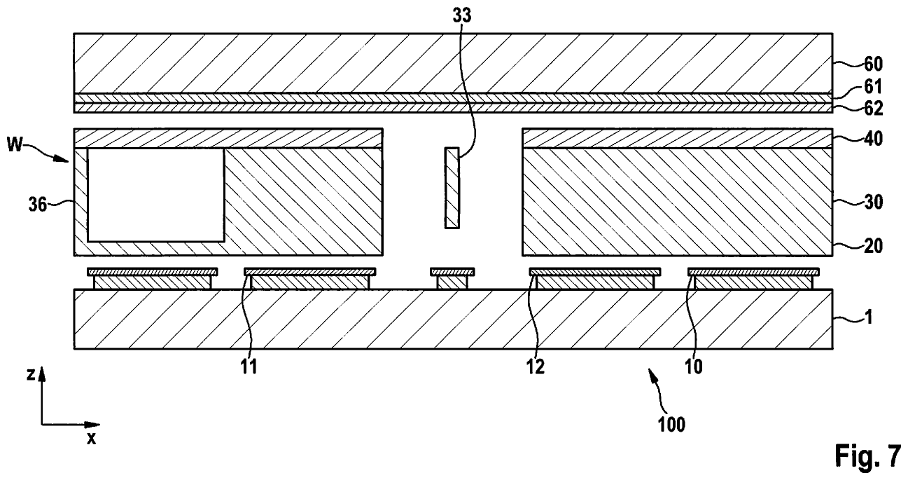

FIG. 7 shows a first specific embodiment of a micromechanical component 100 according to the present invention in the form of a z-acceleration sensor. The figure shows the rocker W rotatable about torsion axis 33 having an additional hollow mass 36 on the light rocker side, which is formed from the three silicon functional layers 20, 30, 40. This design ensures a symmetrization of rocker W with respect to torsion axis 33 not only toward the lower boundary surface of the sensor structure (i.e. between first silicon functional layer 10 and second silicon functional layer 20), but also toward the upper boundary surface between fourth silicon functional layer 40 and cap 60 having an insulating oxide layer 61 and a conductive layer 62 (e.g. in the form of polysilicon or metal).

Advantageously, it is thereby possible to minimize or compensate for radiometric effects with consequences in the form of parasitic deflections of rocker W in the z-direction. Furthermore, this makes it possible to maintain a pronounced mass asymmetry between the left and the right sides of the rocker since the mass on the right rocker side is formed largely (perforation holes are not shown in the figures for the sake of simplicity) from the thick third silicon functional layer 30 and is thus markedly heavier than the left rocker side.

This also ensures that a high mechanical sensitivity of micromechanical component 100 is maintained.

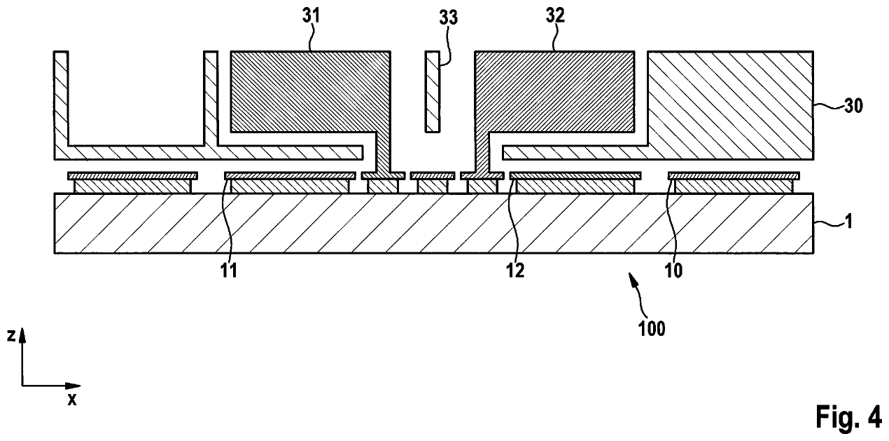

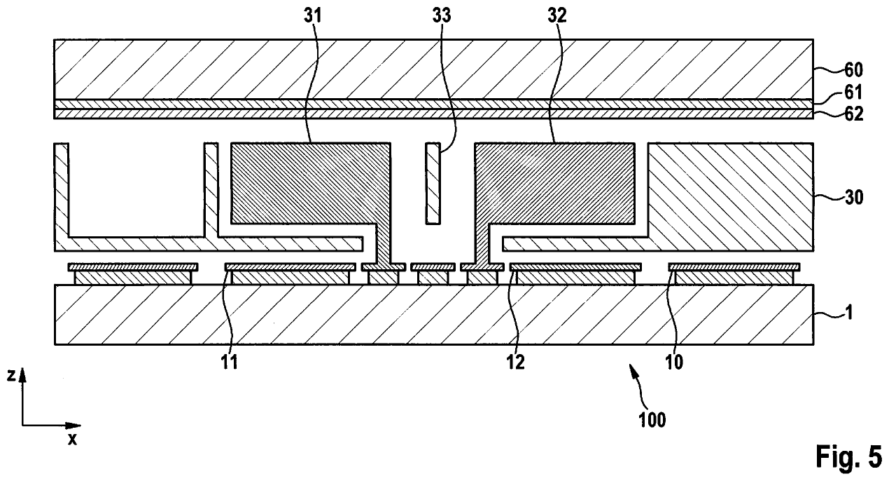

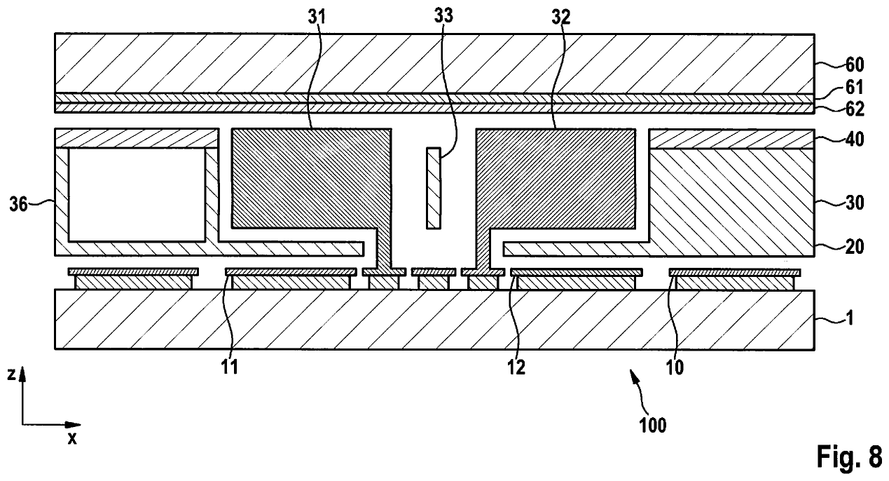

FIG. 8 shows another specific embodiment according to the present invention of a micromechanical component 100 in the form of a z-acceleration sensor. In this case, the design is based on the topology of the conventional design from FIG. 4, the trough-shaped mass body on the left rocker side being replaced, in accordance with the present invention, by a hollow mass covered by fourth silicon functional layer 40, which thereby forms additional hollow mass 36. The evaluation stationary electrodes 31, 32 developed in third silicon functional layer 30 continue to exist as in the conventional design of FIG. 4.

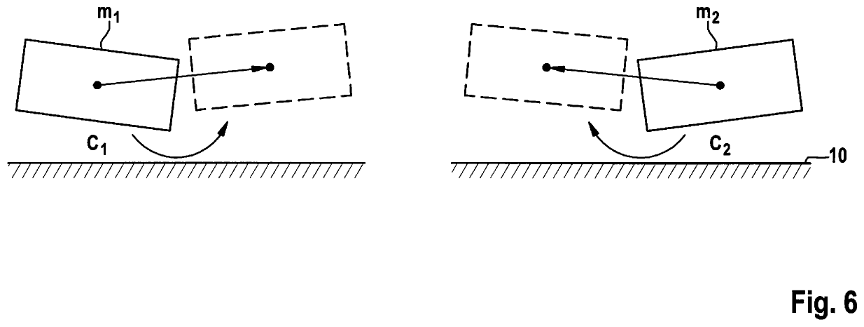

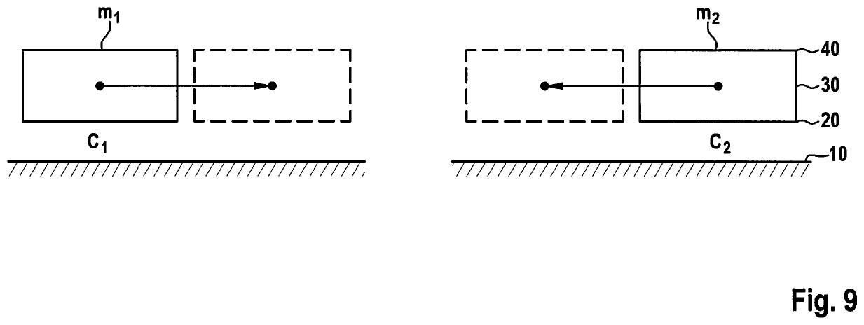

The hollow masses according to the present invention may also be advantageously used in micromechanical components in the form of rotation-rate sensors. In analogy to FIG. 6, FIG. 9 illustrates the oscillatory movement of a driven rotation-rate sensor having two hollow mass bodies m₁ and m₂. In contrast to the conventional design from FIG. 6, the drive movement of the rotation-rate sensor according to the present invention now occurs in good approximation without parasitic z-movement, i.e. essentially in-plane, due to the hollow masses used (in place of the trough-shaped masses in FIG. 6). This is the case at least when the layer thicknesses of the second silicon functional layer 20 and of the fourth silicon functional layer 40 are very similar. Preferably, the layer thicknesses of the second and fourth silicon functional layers 20, 40 differ maximally by 50%, preferably maximally by 25%. This also applies when using the additional hollow mass 36 for z-acceleration sensors. This configuration must thus be regarded as particularly preferred for the rotation-rate sensor (or generally for moved oscillatory masses).

It is additionally particularly preferred that the layer thickness of the third silicon functional layer is chosen to be greater than 8 μm, preferably 10-50 μm, while the layer thicknesses of the second and fourth silicon functional layers may be chosen to be markedly smaller. This advantageously makes it possible on the one hand to achieve hollow masses that are flexurally very stiff, to achieve furthermore great mass differences between hollow masses and filled masses, and finally to achieve stiff springs in the third silicon functional layer, the z-coordinate of the spring coinciding with the z-coordinate of the mass center of the hollow mass and parasitic z-movement components being avoided in an in-plane movement.

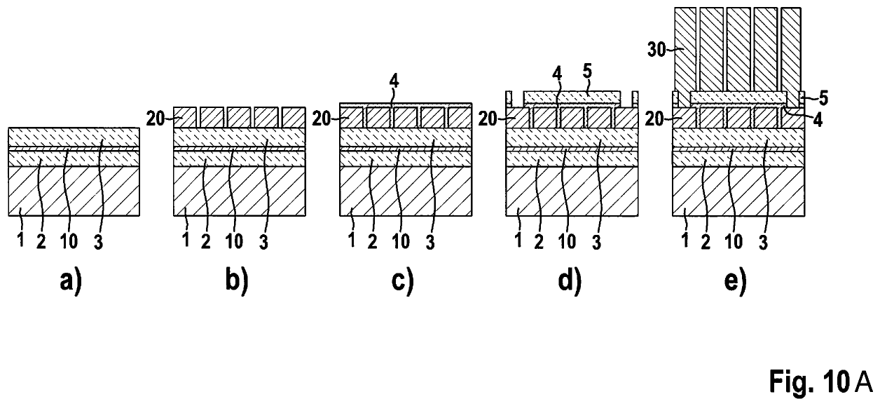

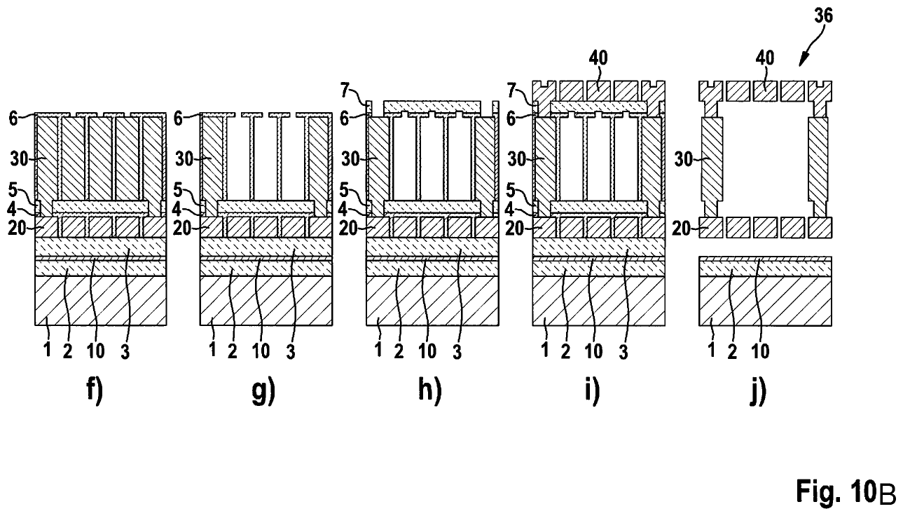

As manufacturing method for the spring geometries provided here, it is possible to use a surface micromechanical process described in more detail below, in which the four silicon functional layers 10, 20, 30 and 40 are used, which are preferably formed from polysilicon. The process sequence is shown in FIGS. 10A and 10B in substeps or substep figures a) through j), that is, only for the partial area of the additional hollow mass 36 to be formed.

In a substep a), a substrate 1 is provided with a first oxide layer 2, the first silicon functional layer 10 and a second oxide layer 3.

In a substep b), the second silicon functional layer 20 is deposited onto second oxide layer 3 and is patterned by fine trenches.

In a substep c), a third oxide layer 4 is deposited, which closes the trenches on top. This is followed by further process steps, which have no visible effect in the area of the shown hollow mass, however, and are therefore not shown in the figures, that is, the opening of third oxide layer 4 through fine slits and a subsequent etching step of the second silicon functional layer 20 (preferably by isotropic SF₆ or XeF₂ etching) through the fine oxide openings.

In substep d), a further oxide layer 5 is deposited, whereby all fine openings in third oxide layer 4 are closed. The advantage of the method lies in the fact that it is possible to clear out large areas of second silicon functional layer 20 without leaving significant topography on the surface of oxide layer 5, as known for example from DE 10 2011 080 978 A1. Subsequently, fourth oxide layer 5 is patterned together with third oxide layer 4 in order to allow for contacts between second silicon functional layer 20 and third silicon functional layer 30.

In a substep e), third silicon functional layer 30 is deposited and patterned via fine trenches.

In a substep f), a fifth oxide layer 6 is deposited, and small openings are created in fifth oxide layer 6.

In an etching step in substep g), which is preferably developed as isotropic SF₆ or XeF₂ etching, sacrificial silicon areas are removed in third silicon functional layer 30.

As indicated, in substep h), the openings in fifth oxide layer 6 are closed again by another oxide layer 7.

Subsequently, seventh oxide layer 7 is patterned together with sixth oxide layer 6 in order to provide electrical contacts between third silicon functional layer 30 and fourth silicon functional layer 40.

In substep i), fourth silicon functional layer 40 is deposited and patterned.

As indicated in substep j), all sacrificial oxides 6, 7 are removed by oxide etching, preferably using gaseous HF, and the sensor structure is exposed.

Ultimately, in substeps a) through j) of FIG. 10, the additional hollow mass 36 is formed with perforation holes in second and fourth silicon functional layers 20, 40.

The provided method offers the possibility of cleaning out large areas of third silicon functional layer 30 and nevertheless covering it almost completely with the (merely slightly perforated) fourth silicon functional layer 40.

For example, a ratio between the area coverage of second silicon functional layer 20 and fourth silicon functional layer 40 on the one hand and the area coverage of third silicon functional layer 30 on the other hand may be significantly greater than three, a ratio of ten being possible as well. This is achieved by the perforations, created using etching technology, in the mentioned silicon functional layers, which, at least in sections, in second and fourth silicon functional layers 20, 40 make up approx. 10% to approx. 20% and in third silicon functional layer make up approx. 80% to approx. 90% of the entire area coverage.

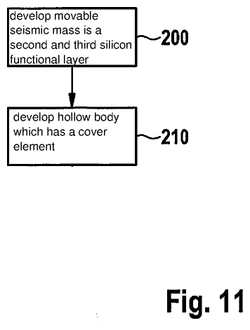

FIG. 11 shows a basic sequence of a method for manufacturing a micromechanical component 100 as provided in the present invention.

In a step 200, a movable seismic mass developed in a second and third silicon functional layer 20, 30 is provided.

In a step 210, a hollow body 36 is developed in the second and third silicon functional layers 20, 30, which has a cover element developed in a fourth silicon functional layer 40.

Although the present invention was described above with reference to concrete exemplary embodiments, in particular acceleration and rotation-rate sensors, one skilled in the art is also able to implement specific embodiments that were not disclosed above or that were disclosed above only partially, without deviating from the essence of the invention. It is in particular possible to use the present invention for other micromechanical components such as e.g. resonators, micromirrors or Lorentz magnetometers.

What is claimed is:

1. A micromechanical component, comprising:
a movable seismic mass developed in a second and third silicon functional layer; and
a hollow body developed in the second and third silicon functional layers, which has a cover element developed in a fourth silicon functional layer).

2. The micromechanical component as recited in claim 1, wherein first electrodes are developed in a first silicon functional layer, the seismic mass being configured to functionally interact with the first electrodes.

3. The micromechanical component as recited in claim 1, wherein second electrodes are developed in the second silicon functional layer or the third silicon functional layer or the fourth silicon functional layer.

4. The micromechanical component as recited in claim 1, wherein a thickness of the second silicon functional layer, the third silicon functional layer, and the fourth silicon functional layer is greater than approx. 1 μm.

5. The micromechanical component as recited in claim 1, wherein a thickness of the third silicon functional layer is greater than approx. 8 μm.

6. The micromechanical component as recited in claim 1, wherein a thickness of the third silicon functional layer is at least twice as great as a thickness of the second silicon functional layer and the fourth silicon functional layer.

7. The micromechanical component as recited in claim 1, wherein a layer thicknesses of the second silicon functional layer and the fourth silicon functional layer are similar in a defined manner.

8. The micromechanical component as recited in claim 7, wherein a layer thicknesses of the second silicon functional layer and the fourth silicon functional layers differ maximally by 50%.

9. The micromechanical component as recited in claim 8, wherein a layer thicknesses of the second silicon functional layer and the fourth silicon functional layers differ maximally by 25%.

10. The micromechanical component as recited in claim 1, wherein, at least in sections, a ratio of an area coverage between the second silicon functional layer and fourth silicon functional layer on the one hand, and the third silicon functional layer on the other hand is between three and ten.

11. The micromechanical component as recited in claim 10, wherein, at least in sections, a ratio of an area coverage between the second silicon functional layer and fourth silicon functional layer on the one hand, and the third silicon functional layer on the other hand is five.

12. The micromechanical component as recited in claim 1, wherein the micromechanical component is an acceleration sensor or a rotation-rate sensor.

13. A method for manufacturing a micromechanical component, comprising the following steps:
providing a movable seismic mass developed in a second silicon functional layer and a third silicon functional layer; and
developing a hollow body in the second silicon functional layer and the third silicon functional layer, which has a cover element developed in a fourth silicon functional layer.
